(19) United States
(12) Patent Application Publication
(10) Pub. No.: US 2020/0135947 A1
(43) Pub. Date: Apr. 30, 2020

(54) SOLAR CELL

(71) Applicant: Industrial Technology Research Institute, Hsinchu (TW)

(72) Inventors: Chun-Ming Yeh, Taipei City (TW); Chorng-Jye Huang, Hsinchu City (TW); Chun-Chieh Lo, Hsinchu County (TW)

(73) Assignee: Industrial Technology Research Institute, Hsinchu (TW)

(21) Appl. No.: 16/243,088

(22) Filed: Jan. 9, 2019

(30) Foreign Application Priority Data
Oct. 26, 2018 (TW) 107138086

(51) Int. Cl. H01L 31/0224; H01L 31/0216; H01L 31/0368

(52) U.S. Cl. CPC H01L 31/022441; H01L 31/03682; H01L 31/02168

(57) ABSTRACT

A solar cell includes an N-type silicon substrate, a P-type doped region, an anti-reflective layer, an n+ back surface field (BSF), aluminum electrodes, aluminum doped regions, and a backside electrode. The N-type silicon substrate has a first surface and a second surface opposite to the first surface. The P-type doped region is formed in the first surface of the N-type silicon substrate. The anti-reflective layer is formed on the P-type doped region. The aluminum electrodes are formed on the P-type doped region, and the aluminum doped regions are formed in the P-type doped region under the aluminum electrodes, wherein the aluminum doped regions are in direct contact with the aluminum electrodes. The n+ BSF is formed in the second surface of the N-type silicon substrate, and the backside electrode is formed on the second surface of the N-type silicon substrate.

### CROSS-REFERENCE TO RELATED APPLICATION

This application claims the priority benefit of Taiwan application serial no. 107138086, filed on Oct. 26, 2018. The entirety of the above-mentioned patent application is hereby incorporated by reference herein and made a part of this specification.

### TECHNICAL FIELD

The disclosure relates to a solar cell.

### BACKGROUND

Due to the shortage of petrochemical energy, people's awareness of the importance of environmental protection raises. Thus, in recent years, people keep devoting themselves in actively developing technologies related to alternative energy and renewable energy in the hope of reducing current people's dependency on the petrochemical energy and mitigating impact that may be caused on the environment by the petrochemical energy. Among a variety of technologies with respect to alternative energy and renewable energy, the technology related to solar cells draws the most attention. This is mainly because a solar cell is capable of directly converting the solar energy into electric energy, without generating any hazardous substances, such as carbon dioxide or nitrides, during a power generation process and thus, will not create any pollution to the environment.

However, a phenomenon of carrier recombination may likely occur between an electrode (metal) and a silicon substrate of the solar cell while a contact impedance between the metal and the substrate is also an issue to be improved. Thus, in order to prevent the carrier recombination between the metal and the substrate and mitigate the contact impedance between the metal and the substrate, a selective emitter structure is manufactured under the metal in a current high-efficiency solar cell, namely, the emitter under the metal has a higher concentration.

Conventionally, in a manufacturing method of a selective electrode structure under metal silver, 6 steps as follows are first performed. A sacrificial layer is first formed, the sacrificial layer is then patterned, a mask paste is provided thereon to expose a part of the sacrificial layer, the mask paste is removed, and after the second boron diffusion, the sacrificial layer is etched. Then, a subsequent process for forming an anti-reflective layer is performed. Therefore, the manufacturing method of such structure is quite difficult and complicated.

### SUMMARY

A solar cell of an embodiment of the disclosure includes an N-type silicon substrate, a P-type doped region, an anti-reflective layer, an n+ back surface field (BSF), aluminum electrodes, aluminum doped regions, and a backside electrode. The N-type silicon substrate has a first surface and a second surface opposite to the first surface. The P-type doped region is formed in the first surface of the N-type silicon substrate. The anti-reflective layer is formed on the P-type doped region. The aluminum electrodes are formed on the P-type doped region, and the aluminum doped regions are formed in the P-type doped region under the aluminum electrodes, wherein the aluminum doped regions are in direct contact with the aluminum electrodes. The n+ BSF is formed in the second surface of the N-type silicon substrate, and the backside electrode is formed on the second surface of the N-type silicon substrate.

A solar cell of another embodiment of the disclosure includes an N-type silicon substrate, a P-type doped region, a polysilicon layer, an anti-reflective layer, an n+ BSF, aluminum electrodes, aluminum doped regions, and a backside electrode. The N-type silicon substrate has a first surface and a second surface opposite to the first surface. The P-type doped region is formed in the first surface of the N-type silicon substrate. The polysilicon layer is formed on the P-type doped region. The anti-reflective layer is formed on the polysilicon layer. The aluminum electrodes are formed on the polysilicon layer, the aluminum doped regions are formed in the polysilicon layer under the aluminum electrodes, wherein the aluminum doped regions are in direct contact with the aluminum electrodes. The n+ BSF is formed in the second surface of the N-type silicon substrate, and the backside electrode is formed on the second surface of the N-type silicon substrate.

To make the above features of the disclosure more comprehensible, embodiments accompanied with drawings are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional view of a solar cell according to a first embodiment of the disclosure.

FIG. 2 is a schematic cross-sectional view of a solar cell according to a second embodiment of the disclosure.

### DESCRIPTION OF EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

Exemplary embodiments of the disclosure will be comprehensively described with the accompanying drawings. However, the disclosure may still be implemented in many other different forms and should not be construed as limitations to the embodiments described hereinafter. In the drawings, each area, each portion and a size and a thickness of each layer may not illustrate according to actual proportions. For convenient comprehension, the same elements are labeled by the same referral symbols in the following description.

In the present disclosure, the metal aluminum serves both the front electrodes and a dopant source of the selective emitter (i.e., a p++ doped region), so as to achieve mitigating the loss due to the contact between the electrodes and the substrate and reducing the cost by the simple manufacturing process. Moreover, in the disclosure, the silicon substrate and the metal aluminum can be separated from each other by the polysilicon layer, thereby preventing the substrate from being damaged by a laser drilling process when the aluminum electrodes are manufactured and achieving surface passivation for other regions of the substrate by the polysilicon layer. Thus, the minority carrier recombination can be further reduced.

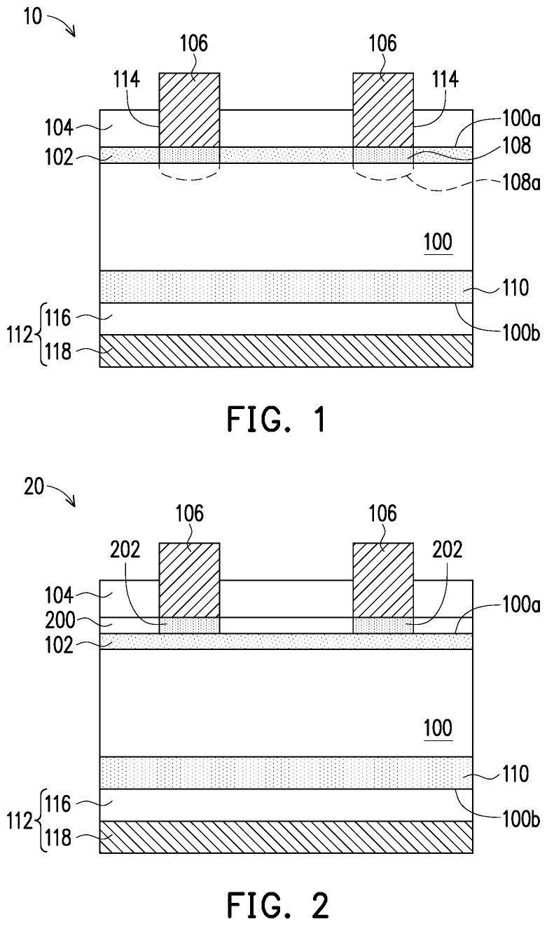

FIG. 1 is a schematic cross-sectional view of a solar cell according to a first embodiment of the disclosure.

Referring to FIG. 1, a solar cell of the first embodiment at least includes an N-type silicon substrate 100, a P-type doped region 102, an anti-reflective layer 104, aluminum electrodes 106, aluminum doped regions 108, an n+ back surface field (BSF) 110 and a backside electrode 112. The N-type silicon substrate 100 has a first surface 100a and a second surface 100b opposite to the first surface 100a. The P-type doped region 102 is formed in the first surface 100a of the N-type silicon substrate 100, wherein a dopant of the P-type doped region 102 includes, for example, boron, aluminum, gallium, indium, thallium, germanium or a combination of the aforementioned elements. The anti-reflective layer 104 and the aluminum electrodes 106 are both formed on the P-type doped region 102. In other words, the anti-reflective layer 104 is disposed on the N-type silicon substrate other than those positions where the aluminum electrodes 106 are disposed, thereby reducing a probability that incident light is reflected outwards by the N-type silicon substrate 100. By observing a manufacturing process, the entire anti-reflective layer 104 may be first formed on the P-type doped region 102, openings are formed in the anti-reflective layer 104 by, for example, a laser drilling process to expose the first surface 100a, and then, the aluminum electrodes 106 are formed in the openings 114. In an embodiment, the anti-reflective layer 104 may be a single-layer structure, and a material thereof may include aluminum oxide (Al₂O₃), silicon nitride (SiN), silicon oxide (SiO₂), silicon oxynitride (SiON) or a combination thereof. In another embodiment, the anti-reflective layer 104 may be a multi-layer structure, and a material thereof may include aluminum oxide/silicon nitride, aluminum oxide/silicon oxide or aluminum oxide/silicon oxynitride.

Continuously referring to FIG. 1, the aluminum doped regions 108 are formed in the P-type doped region 102 under the aluminum electrodes 106, and a method of forming the aluminum doped regions 108 is, for example, employing the aluminum electrodes 106 as a dopant source and diffusing and doping aluminum ions from the aluminum electrodes 106 into the P-type doped region 102 by a high-temperature process. Thus, the aluminum doped regions 108 are in direct contact with the aluminum electrodes 106, and therefore, the manufacturing process is simplified. Additionally, the aluminum doped regions 108 may further extend into the N-type silicon substrate 100, such that a depth (i.e., an extending region 108a) of each of the aluminum doped regions 108 is deeper than that of the P-type doped region 102. In the present embodiment, the aluminum doped regions 108 may have a doping concentration which is double or more than a doping concentration of the P-type doped region 102 to serve as a p++ selective emitter, thereby reducing a contact resistance between the aluminum electrodes 106 and the N-type silicon substrate 100, wherein an aluminum doping concentration of the aluminum doped regions 108 may range from 1×10¹⁹ cm⁻³ to 1×10²¹ cm⁻³. Moreover, the aluminum doped regions 108 may be continuous regions or non-continuous regions. For example, the continuous regions may be linear regions, while the non-continuous regions may be dot regions or dashed regions. Regarding the n+ BSF 110, it is formed in the second surface 100b of the N-type silicon substrate 100, and the backside electrode 112 is formed on the second surface 100b of the N-type silicon substrate. In FIG. 1, the n+ BSF 110 is a full BSF, and the backside electrode 112 includes a transparent conductive layer (also known as “TCO”) 116 (wherein TCO may be exemplified as ITO, ZnO, TiO₂, IWO or In₂O₃:Zr) and a metal layer 118 (for example, an aluminum layer, a silver layer or the like). However, the disclosure is not limited thereto, and any design of the backside electrode for N-type solar cells is applicable to the present embodiment. For example, the n+ BSF 110 may be a local BSF, and a passivation layer (not shown) with openings may be additionally disposed on the second surface 100b of the N-type silicon substrate 100, such that the backside electrode 112 on the second surface 100b of the N-type silicon substrate 100 may be in contact with the local n+ BSF through the openings of the passivation layer.

FIG. 2 is a schematic cross-sectional view of a solar cell according to a second embodiment of the disclosure, wherein the same or similar elements are represented by using the same element symbols in FIG. 1, and a part of the technical description which is omitted, such as the size, material, doping concentration and function of each layer or region may refer to the content related to the embodiment illustrated in FIG. 1 and thus, will not be repeated.

Referring to FIG. 2, the difference between a solar cell 20 of the second embodiment and that of the first embodiment mainly lies in that a polysilicon layer 200 is further disposed between the P-type doped region 102 and the anti-reflective layer 104, such that aluminum doped regions 202 are formed in the polysilicon layer 200 under aluminum electrodes 106. Since the aluminum electrodes 106 may be formed in the way as described in the first embodiment, i.e., positions in the anti-reflective layer 104 where the aluminum electrodes 106 are to be formed are gashed by a laser drilling process, a polysilicon layer 200 is first formed on the first surface 100a of the N-type silicon substrate 100, such that the P-type doped region 102 may be effectively prevented from being damaged due to the laser drilling process as well as achieve surface passivation to separate the aluminum electrodes 106 from the P-type doped region 102 to form a passivated contact, thereby reducing carrier recombination. In the present embodiment, a material of the polysilicon layer 200 includes, for example, polysilicon, polycrystalline silicon oxide, polycrystalline silicon carbide, any other polysilicide or a combination thereof. Additionally, a thickness of the polysilicon layer 200 ranges, for example, from 10 nm to 500 nm to ensure the passivation effect without influencing light entering the solar cell 20. In addition, the polysilicon layer 200 illustrated in FIG. 2 is an entire-surface film layer, but the disclosure is not limited thereto. In another embodiment, the polysilicon layer 200 may also be partially formed on the first surface 100a of the N-type silicon substrate 100 to be located between the aluminum electrodes 106 and the P-type doped region 102. Regarding the formation, a doping concentration, an occupied area and the like of the aluminum doped regions 202, reference may be made to the first embodiment. In addition, the aluminum doped regions 202 may also extend into the P-type doped region 102 or further extend into the N-type silicon substrate 100, thereby further reducing the probability of the carrier recombination to increase an open-circuit voltage of the solar cell 20.

Several experiments are numerated below for verifying the effects of the disclosure, but the scope of the disclosure is not limited to the experiment examples below.

### Experiment Example 1

To manufacture a solar cell as illustrated in FIG. 1, a boron-doped P-type doped region was formed on a front surface of a silicon crystal (C—Si) chip to serve as an emitter, a back surface of the chip was polished, an n+ BSF was manufactured, an anti-reflective layer (including an Al₂O₃ layer and an SiN layer) on the front surface of the chip, a minority carrier life time (MCLT) and an implied open circuit voltage (iVoc) were measured, and results thereof were recorded in Table 1 below.

Then, openings (with a width ranging about 10 μm to 15 μm) were formed in the anti-reflective layer by a laser drilling process, an MCLT and an iVoc after the laser drilling process were measured, and results thereof were recorded in Table 2 below.

Thereafter, an aluminum paste was formed on portions of the openings by screen printing, and a sintering process was performed (with a maximum temperature about 700° C. in a sintering furnace for a sintering duration of 1 to 3 minutes) to form aluminum electrodes by the aluminum paste and to diffuse and dope aluminum ions from the aluminum electrodes into the P-type doped region, thereby completing aluminum doped regions (Al-p++), an MCLT and an iVoc were measured, and results thereof were recorded in Table 3 below.

Finally, a backside electrode (including a transparent conductive layer and a metal layer) was manufactured on the back surface of the chip, thereby completing the solar cell, and an open circuit voltage (Voc) thereof was measured and recorded in Table 4 below.

### Experiment Example 2

To manufacture a solar cell as illustrated in FIG. 2, a manufacturing process which is substantially the same as that in Experiment Example 1 is used, however, before an anti-reflective layer was formed, a polysilicon (intrinsic polysilicon, also known as “I-poly”) layer was first formed on a front surface of a chip. Manufacturing parameters of the polysilicon layer were set as follows: low pressure chemical vapour deposition (LPCVD) was used, a temperature was 580° C., a pressure was 150 mtorr, and a deposition source was SiH₄.

In the same way, the measurement was taken before a laser drilling process was performed, after the laser drilling process was performed, upon the completion of aluminum doped regions and upon the completion of the solar cell, and results thereof were recorded in Tables 1 to 4 below.

### Experiment Example 3

A manufacturing process which is substantially the same as that in Experiment Example 2 was used, but the polysilicon layer was replaced by a polycrystalline silicon oxide (I-oxide poly) layer. Manufacturing parameters of the polycrystalline silicon oxide layer were set as follows: LPCVD was used, a temperature was 580° C., a pressure was 150 mtorr, and a deposition source was SiH₄/N₂O=1:1.

In the same way, the measurement was performed before the laser drilling process was performed, after the laser drilling process was performed, upon the completion of the aluminum doped regions and upon the completion of the solar cell, and results thereof were recorded in Tables 1 to 4 below.

### Comparative Example

A boron-doped P-type doped region was formed on a front surface of a C—Si chip to serve as an emitter, a back surface of the chip was polished, an n+ BSF was manufactured, an anti-reflective layer (including an Al₂O₃ layer and an SiN layer) was formed on the front surface of the chip, an MCLT and an iVoc thereof were measured, and results thereof were recorded in Table 1 below.

A silver paste was formed on the anti-reflective layer by screen printing, and a sintering process was performed (with a temperature about 760° C. in a sintering furnace for a sintering duration of 1 to 3 minutes) to form silver electrodes by the silver paste, which fire through the anti-reflective layer, an MCLT and an iVoc were measured, and results thereof were recorded in Table 3 below.

Finally, a backside electrode (including a transparent conductive layer and a metal layer) was manufactured on the back surface of the chip to complete the solar cell, and a Voc thereof was measured and recorded in Table 4 below.

TABLE 1

| | Comparative | | Experiment | | Experiment | | Experiment | |
|---|---|---|---|---|---|---|---|---|
| | Example | | Example 1 | | Example 2 | | Example 3 | |
| MCLT | 560 | μs | 560 | μs | 626 | μs | 803 | μs |
| iVoc | 690 | mV | 690 | mV | 687 | mV | 694 | mV |

TABLE 2

| | Comparative | | Experiment | | Experiment | | Experiment | |
|---|---|---|---|---|---|---|---|---|
| | Example | | Example 1 | | Example 2 | | Example 3 | |
| MCLT | 560 | μs | 154 | μs | 540 | μs | 550 | μs |
| iVoc | 690 | mV | 660 | mV | 680 | mV | 685 | mV |

Comparative Example does not perform the laser drilling process and thus, data thereof is the same as those in Table 1.

TABLE 3

| | Comparative | | Experiment | | Experiment | | Experiment | |
|---|---|---|---|---|---|---|---|---|
| | Example | | Example 1 | | Example 2 | | Example 3 | |
| MCLT | 308 | μs | 409 | μs | 448 | μs | 505 | μs |
| iVoc | 666 | mV | 676 | mV | 683 | mV | 686 | mV |

TABLE 4

| | Comparative | Experiment | Experiment | Experiment |
|---|---|---|---|---|
| | Example | Example 1 | Example 2 | Example 3 |
| Voc | 661 mV | 671 mV | 675 mV | 678 mV |

According to Tables 1 to 4, the data after the laser drilling process is performed are relatively lower than those in the Comparative Example (Table 2), but the Voc after the solar cell is completed is obviously higher than that of the Comparative Example.

Based on the above, the disclosure directly utilizes the sintering process of aluminum electrodes to diffuse and dope aluminum ions into the P-type doped region to form the aluminum doped regions (Al-p++) to replace the p++ regions which are additionally doped under the metal electrode to serve as the selective emitter structure in the related art, which achieves low cost and simplicity of the manufacturing process, thereby extending the life time and increasing the open circuit voltage for the cell. Moreover, a polysilicon layer is additionally disposed in the disclosure, the substrate can be prevented from being damage due to the laser drilling process, the life time can be extended, and the open circuit voltage of the cell can be increased.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A solar cell, comprising:
an N-type silicon substrate, having a first surface and a second surface opposite to the first surface;
a P-type doped region, formed in the first surface of the N-type silicon substrate;
an anti-reflective layer, formed on the P-type doped region;
an n+ back surface field (BSF), formed in the second surface of the N-type silicon substrate;
a plurality of aluminum electrodes, formed on the P-type doped region;
a plurality of aluminum doped regions, formed in the P-type doped region under the aluminum electrodes and being in direct contact with the aluminum electrodes; and
a backside electrode, formed on the second surface of the N-type silicon substrate.

2. The solar cell as recited in claim 1, wherein the aluminum doped regions further extend into the N-type silicon substrate, such that a depth of each of the aluminum doped regions is deeper than a depth of the P-type doped region.

3. The solar cell as recited in claim 1, wherein the aluminum doped regions has a doping concentration which is double or more than a doping concentration of the P-type doped region.

4. The solar cell as recited in claim 1, wherein a dopant of the P-type doped region comprises boron, aluminum, gallium, indium, thallium, germanium or a combination thereof.

5. The solar cell as recited in claim 1, wherein the aluminum doped regions are continuous regions or non-continuous regions.

6. The solar cell as recited in claim 5, wherein the continuous regions comprise linear regions.

7. The solar cell as recited in claim 5, wherein the non-continuous regions comprise dot regions or dashed regions.

8. The solar cell as recited in claim 1, wherein the anti-reflective layer is a single-layer or a multi-layer structure.

9. The solar cell as recited in claim 1, wherein the n+ BSF is a full BSF or a local BSF.

10. A solar cell, comprising:
an N-type silicon substrate, having a first surface and a second surface opposite to the first surface;
a P-type doped region, formed in the first surface of the N-type silicon substrate;
a polysilicon layer, formed on the P-type doped region;
an anti-reflective layer, formed on the polysilicon layer;
a plurality of aluminum electrodes, formed on the polysilicon layer;
a plurality of aluminum doped regions, formed in the polysilicon layer under the aluminum electrodes and being in direct contact with the aluminum electrodes;
an n+ back surface field (BSF), formed in the second surface of the N-type silicon substrate; and
a backside electrode, formed on the second surface of the N-type silicon substrate.

11. The solar cell as recited in claim 10, wherein a material of the polysilicon layer comprises polysilicon, polycrystalline silicon oxide, polycrystalline silicon carbide or a combination thereof.

12. The solar cell as recited in claim 10, wherein a thickness of the polysilicon layer ranges from 10 nm to 500 nm.

13. The solar cell as recited in claim 10, wherein the aluminum doped regions further extend into the P-type doped region.

14. The solar cell as recited in claim 10, wherein the aluminum doped regions has a doping concentration which is double or more than a doping concentration of the P-type doped region.

15. The solar cell as recited in claim 10, wherein a dopant of the P-type doped region comprises boron, aluminum, gallium, indium, thallium, germanium or a combination thereof.

16. The solar cell as recited in claim 10, wherein the aluminum doped regions are continuous regions or non-continuous regions.

17. The solar cell as recited in claim 16, wherein the continuous regions comprise linear regions.

18. The solar cell as recited in claim 16, wherein the non-continuous regions comprise dot regions or dashed regions.

19. The solar cell as recited in claim 10, wherein the anti-reflective layer is a single-layer or a multi-layer structure.

20. The solar cell as recited in claim 10, wherein the n+ BSF is a full BSF or a local BSF.
